(19) United States
(12) Patent Application Publication
(10) Pub. No.: US 2018/0364575 A1
(43) Pub. Date: Dec. 20, 2018

(54) COATING COMPOSITIONS FOR USE WITH AN OVERCOATED PHOTORESIST

(71) Applicant: Rohm and Haas Electronic Materials Korea Ltd., Cheonan (KR)

(72) Inventors: Hye-Won Lee, Hwaseong (KR); Jae Hwan Sim, Cheonan (KR); Soo Jung Leem, Cheonan (KR); Jin Hong Park, Hwaseong (KR); You Rim Shin, Hwaseong (KR)

(21) Appl. No.: 15/624,701

(22) Filed: Jun. 15, 2017

(51) Int. Cl. G03F 7/09; C08G 18/09; C08G 18/32; C08G 18/16; C09D 175/04; G03F 7/16; G03F 7/20; G03F 7/26

(52) U.S. Cl. CPC G03F 7/091; C08G 18/092; C08G 18/3206; G03F 7/26; C09D 175/04; G03F 7/162; G03F 7/20; C08G 18/168

(57) ABSTRACT

In a preferred aspect, organic coating compositions, particularly antireflective coating compositions for use with an overcoated photoresist, are provided that comprise 1) one or more substituted uracil moieties; and 2) one or more reacted dicarboxylic acid groups.

### BACKGROUND

The present invention relates to compositions and, in particular, antireflective coating compositions for use in microelectronic application. Preferred compositions of the invention comprise a resin with one or more substituted uracil moieties and one or more reacted aliphatic dicarboxylic acid groups. Preferred compositions of the invention are used with an overcoated photoresist composition and may be referred to as bottom antireflective compositions or “BARCs”.

Photoresists are photosensitive films used for the transfer of images to a substrate. A coating layer of a photoresist is formed on a substrate and the photoresist layer is then exposed through a photomask to a source of activating radiation. Following exposure, the photoresist is developed to provide a relief image that permits selective processing of a substrate.

Reflection of activating radiation used to expose a photoresist often poses limits on resolution of the image patterned in the photoresist layer. Reflection of radiation from the substrate/photoresist interface can produce spatial variations in the radiation intensity in the photoresist, resulting in non-uniform photoresist linewidth upon development. Radiation also can scatter from the substrate/photoresist interface into regions of the photoresist where exposure is non-intended, again resulting in linewidth variations.

One approach used to reduce the problem of reflected radiation has been the use of a radiation absorbing layer interposed between the substrate surface and the photoresist coating layer. See US 20030004901; 76915556; US 2006057501; US 2011/0033801; JP05613950B2; JP05320624B2; and KR1270508B1.

For many high performance lithographic applications, particular antireflective compositions are utilized in order to provide the desired performance properties, such as optimal absorption properties and coating characteristics. See, for instance, the above-mentioned patent documents. Nevertheless, electronic device manufacturers continually seek increased resolution of a photoresist image patterned over antireflective coating layers and in turn demand ever-increasing performance from an antireflective composition.

To obtain higher resolution, the desired time to etch the bottom antireflective coating (BARC) has decreased. Reduced etch time can minimize damage of the imaged resist layer thereby enhancing resolution. The etch rate of the underlying composition layer relative to that of the photoresist can determine how much resist is lost during a dry etch step. Fast etching of BARC is increasingly demanded by chip manufacturers.

It thus would be desirable to have new antireflective compositions for use with an overcoated photoresist. It would be particularly desirable to have new antireflective compositions that exhibit enhanced performance and could provide increased resolution of an image patterned into an overcoated photoresist. Among other properties, underlying coating composition that exhibit fast dry etch rates would be highly desirable.

### SUMMARY

We now provide new underlying coating compositions that comprise one or more resins that comprise 1) one or more substituted uracil moieties; and 2) one or more reacted diacid groups. As referred to herein, a diacid group will have two carboxy (—COOH) moieties prior to reaction with other materials to form a resin.

In certain preferred aspects, the coating composition resin may further comprise 3) one or more substituted isocyanurate moieties.

We have found that preferred coating compositions of the invention can exhibit fast etch rates in resist plasma etchants. See, for instance, the results set forth in the examples which follow.

Preferred uracil moieties of resins of the compositions are substituted by electronegative groups such as nitro and halogen particularly fluoro. Preferred reacted diacid groups of resins of compositions of the invention include diacid groups that do not have aromatic substitution (i.e. aliphatic diacid groups).

Preferred resins of the compositions have relatively high Ohnishi parameter values such as at least 7, more preferably 7 to 14 or 8 to 12 or 9 to 12. As referred to herein, an Ohnishi parameter value is representative of the effective carbon content in a polymer as a function of NT/(NC—NO), where NT is the total number of atoms, NC is the number of carbon atoms, and NO is the number of oxygen atoms.

Preferred resins of the invention include those resins that comprise the uracil and reacted dicarboxylic acid components in an amount of 20 to 70 weight percent based on resin total weight, even more preferably where the uracil and reacted dicarboxylic acid components are present in an amount of 20 or 30 to 40, 50 or 60 weight percent based on resin total weight.

Preferred coating compositions of the invention also may comprise a separate crosslinker component. Such a crosslinker can react with the resin component such as during thermal treatment of a coating layer of the composition prior to applying a photoresist layer thereover. Preferred crosslinkers included amine-based materials such as a glycoluril material.

In use with an overcoated photoresist, a coating composition may be applied on a substrate such as a semiconductor wafer which may have one or more organic or inorganic coating layers thereon. The applied coating layer may be optionally thermally treated prior to overcoating with a photoresist layer. As mentioned, such thermal treatment may cause hardening including crosslinking of the coating composition layer. Such crosslinking may include hardening and/or covalent-bonding forming reactions between one or more composition components and can modulate water contact angle of the coating composition layer.

Thereafter, a photoresist composition may be applied over the coating composition layer followed by imaging of the applied photoresist composition layer with patterned activating radiation and the imaged photoresist composition layer is developed to provide a photoresist relief image.

A variety of photoresists may be used in combination (i.e. overcoated) with a coating composition of the invention. Preferred photoresists for use with the underlying coating compositions of the invention are chemically-amplified resists that contain one or more photoactive compounds and a resin component that contains units that undergo a deblocking or cleavage reaction in the presence of photogenerated acid.

The invention further provides methods for forming a photoresist relief image and novel articles of manufacture comprising substrates (such as a microelectronic wafer substrate) coated with a coating composition of the invention alone or in combination with a photoresist composition.

Other aspects of the invention are disclosed infra.

### BRIEF DESCRIPTION OF DRAWING

FIG. 1 is a graph showing etch results evaluation of Examples 1-4 of the invention.

### DETAILED DESCRIPTION

As discussed, we now provide new underlying coating compositions that comprise one or more resins that comprise 1) one or more substituted uracil moieties (e.g. formula (I) below); and 2) one or more reacted diacid groups (e.g. formula (III below)). In certain preferred aspects, the coating composition resin may further comprise 3) one or more substituted isocyanurate moieties (e.g. formula (II below)). As discussed, a diacid group will have two carboxy (—COOH) moieties prior to reaction with other materials to form a resin. Preferred diacid groups may contain additional oxygen content such as one or more ether linkages (suitably 1, 2 or 3 ether linkages) and one or more hydroxyl groups (suitably 1, 2 or 3 hydroxy groups). In certain aspects, preferred diacid groups do not contain any aromatic moieties. In certain additional aspects, preferred diacid groups do not contain any carbon-carbon unsaturated bonds.

In one aspect, the polymer may be obtainable from monomers or resins comprising substituted uracil moieties having a formula:

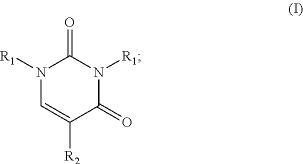

wherein:

R₁ may be hydrogen, —C(O)R, —C(O)OR, substituted or unsubstituted C₁-C₁₂ alkyl (e.g. unsubstituted C₁-C₁₂ alkyl and C₁-C₁₂ haloalkyl), substituted or unsubstituted 2-5 membered heteroalkyl (e.g. substituted or unsubstituted C₁-C₁₂ alkyl alcohol, substituted or unsubstituted C₁-C₁₂ alkyl carboxyl, substituted or unsubstituted C₁-C₁₂ alkyl ester, substituted or unsubstituted C₁-C₁₂ alkyl amine, or substituted or unsubstituted C₁-C₁₂ alkyl aldehyde), substituted or unsubstituted C₃-C₆ cycloalkyl, substituted or unsubstituted 5 to 6 membered heterocycloalkyl, substituted or unsubstituted phenyl, or substituted or unsubstituted 5 to 6 membered heteroaryl;

R₂ may be hydrogen, halogen, —NO₂, —N₃, —CN, —C(O)R, —C(O)OR, —C(O)H, —C(O)OH, —C(O)OCH₃, —OH, —OCH₃, —SO₂R, —S(O₂)OR, —NHR, —NHRR′, substituted or unsubstituted C₁-C₁₂ alkyl (e.g. unsubstituted C₁-C₁₂ alkyl and C₁-C₁₂ haloalkyl), substituted or unsubstituted 2-12 membered heteroalkyl (e.g. substituted or unsubstituted C₁-C₁₂ alkyl alcohol, substituted or unsubstituted C₁-C₁₂ alkyl carboxyl, substituted or unsubstituted C₁-C₁₂ alkyl ester, substituted or unsubstituted C₁-C₁₂ alkyl amine, or substituted or unsubstituted C₁-C₁₂ alkyl aldehyde), substituted or unsubstituted C₃-C₆ cycloalkyl, substituted or unsubstituted 5 to 8 membered heterocycloalkyl, substituted or unsubstituted 5 to 12 membered aryl (e.g. phenyl, anthracene, or naphthyl), or substituted or unsubstituted 5 to 8 membered heteroaryl; and

R and R′ may independently be hydrogen or substituted or unsubstituted C₁-C₃ alkyl, or substituted or unsubstituted C₁-C₃ heteroalkyl such as substituted or unsubstituted C₁-C₃ alkyl alcohol, substituted or unsubstituted C₁-C₁₂ alkyl carboxyl, or substituted or unsubstituted C₁-C₁₂ alkyl amine.

Preferred R₁ includes C₁-C₄ alkyl carboxylic acids or C₁-C₄ alkyl ester, which may be branched or linear and optionally substituted with unsubstituted C₁-C₃ alkyl, unsubstituted C₁-C₃ alkoxy, or C₁-C₃ haloalkyl. Preferred R₂ includes halogen, —NO₂, —N₃, —CN, —C(O)R, —C(O)OR, —C(O)H, —C(O)OH, —C(O)OCH₃, —OH, —OCH₃, —SO₂R, —S(O₂)OR. Other preferred R₂ may include electron-withdrawing group such as halogen, —NO₂, —N₃, or —CN.

Exemplary substituted uracil moieties may include:

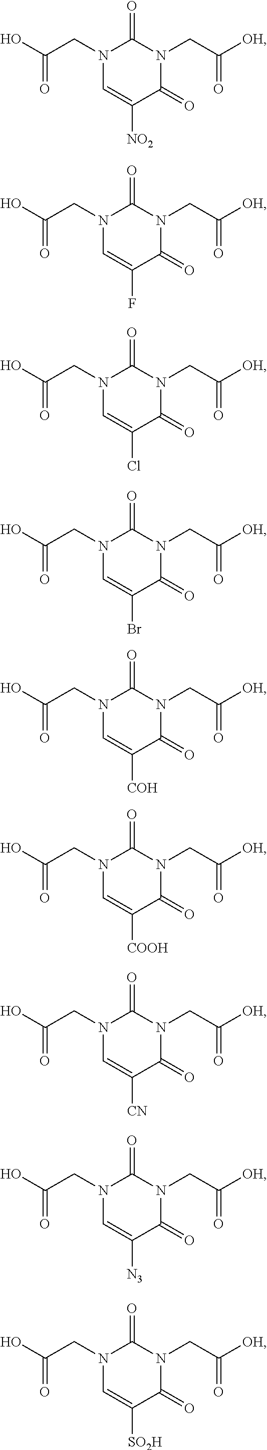

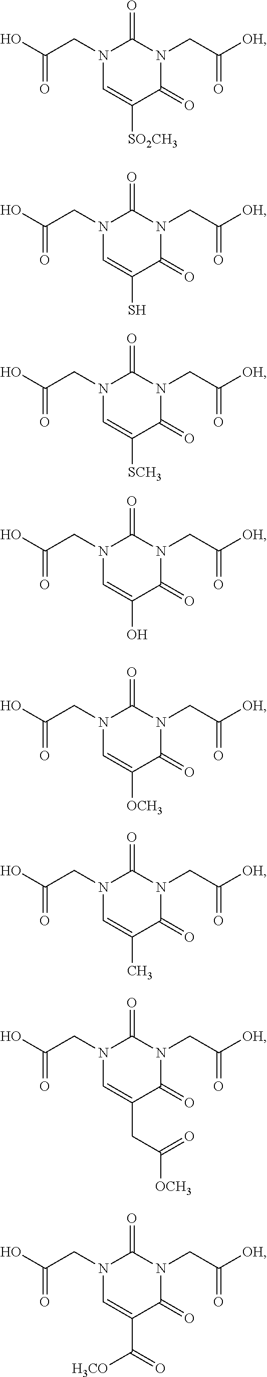

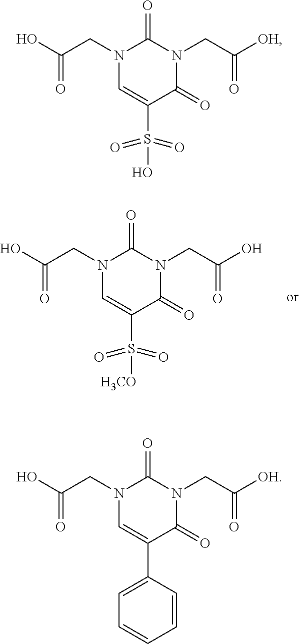

In one aspect, the polymer may be obtainable from monomers or resins comprising one or more isocyanurate moieties having a formula (II):

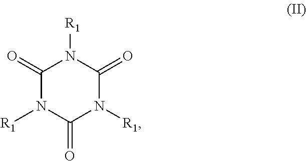

wherein R₁ is suitably hydrogen or a non-hydrogen substitution. Preferred R₁ includes substituted or unsubstituted C₁-C₄ alkyl alcohol, substituted or unsubstituted C₁-C₄ alkyl carboxyl group, or substituted or unsubstituted C₁-C₄ alkyl ester group, which may be branched or linear and optionally substituted with C₁-C₃ alkyl, unsubstituted C₁-C₃ alkoxy, or C₁-C₃ haloalkyl.

Exemplary substituted isocyanurate monomers may include:

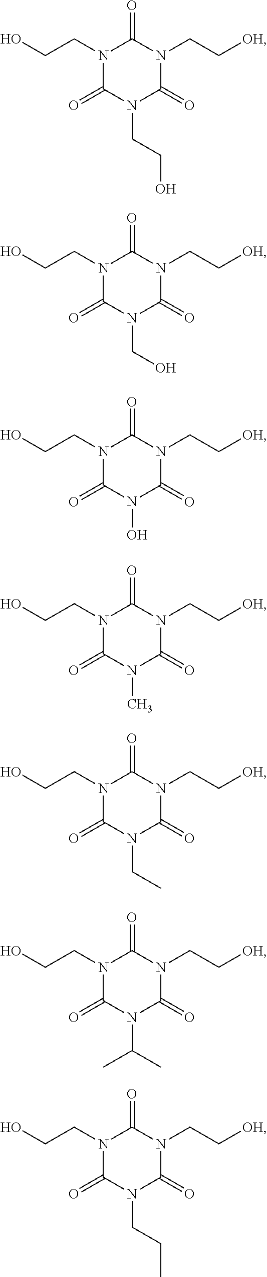

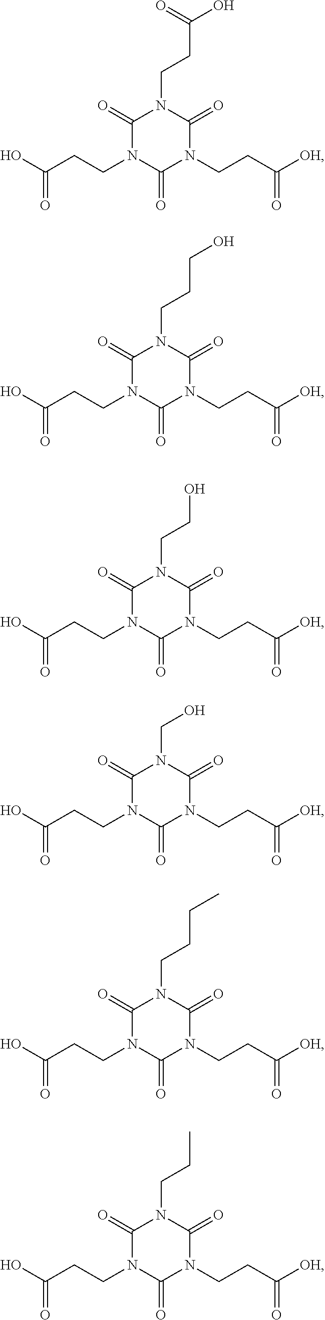 [SMILES: O=C(O)CCn1c(=O)n(CCC(=O)O)c(=O)n(CCC(=O)O)c1=O ; O=C(O)CCn1c(=O)n(CCCO)c(=O)n(CCC(=O)O)c1=O ; O=C(O)CCn1c(=O)n(CCO)c(=O)n(CCC(=O)O)c1=O ; O=C(O)CCn1c(=O)n(CO)c(=O)n(CCC(=O)O)c1=O ; CCCCn1c(=O)n(CCC(=O)O)c(=O)n(CCC(=O)O)c1=O ; CCCn1c(=O)n(CCC(=O)O)c(=O)n(CCC(=O)O)c1=O]

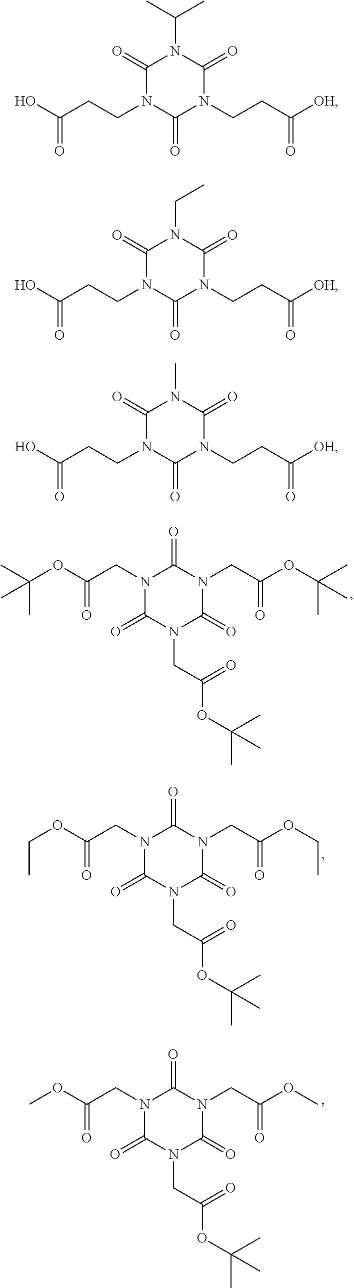

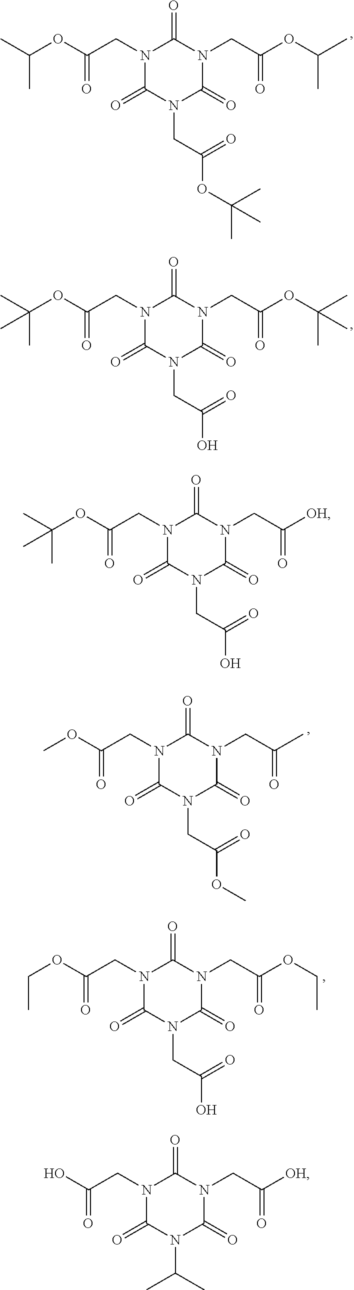

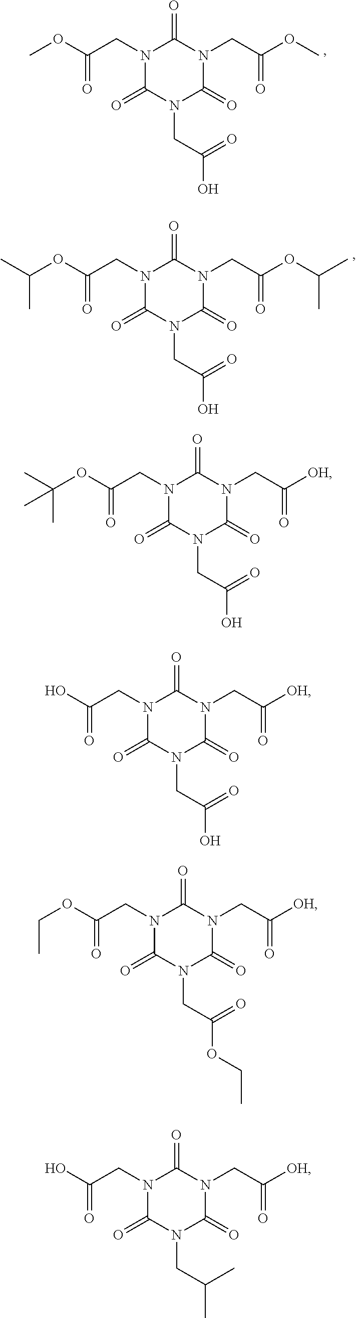

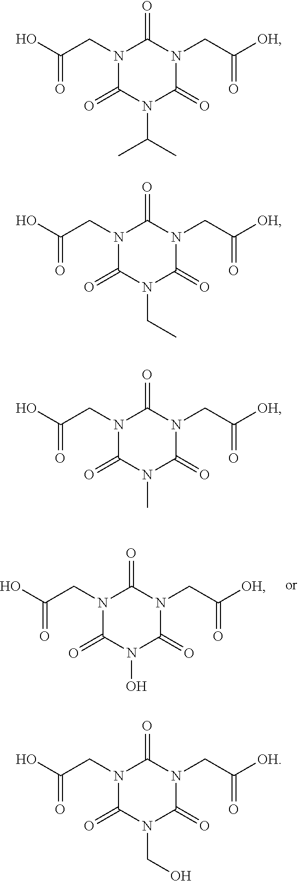

In one aspect, the polymer may be obtainable from monomers or resins comprising dicarboxylic acid groups having a formula (III)

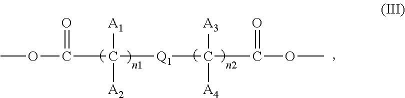

wherein:
n1 and n2 may independently be an integer from 0 to 100;
Q₁ may be independent a bond, —O—, —S—, —NHR— or —CRR′—;
A₁, A₂, A₃ and A₄ may be independently hydrogen, aliphatic groups (e.g. C₁-C₁₂ alkyl), or substituted or unsubstituted C₁-C₁₂ heteroalkyl (e.g. C₁-C₁₂ alkyl alcohol); and
R and R′ are described herein.

Preferred Q₁ is a bond, —O—, or —CRR′—, wherein R and R′ are independently hydrogen, C₁-C₄ alkyl, or C₁-C₄ alkyl alcohol. Preferred A₁, A₂, A₃ and A₄ may independently be hydrogen, linear or branched C₁-C₄ alkyl such as methyl and ethyl, or a C₁-C₄ alkyl alcohol. Preferred n1 and n2 are independently an integer from 0 to 30, from 0 to 10, or from 0 to 5.

Exemplary aliphatic dicarboxylic acid groups may include:

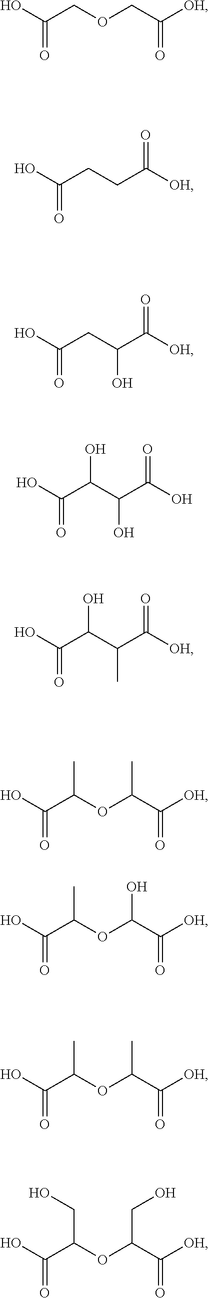

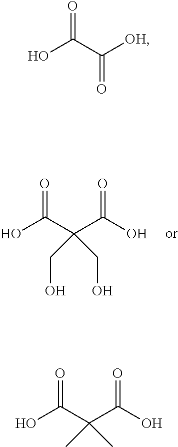

Exemplary preferred polymers may comprise the following structures:

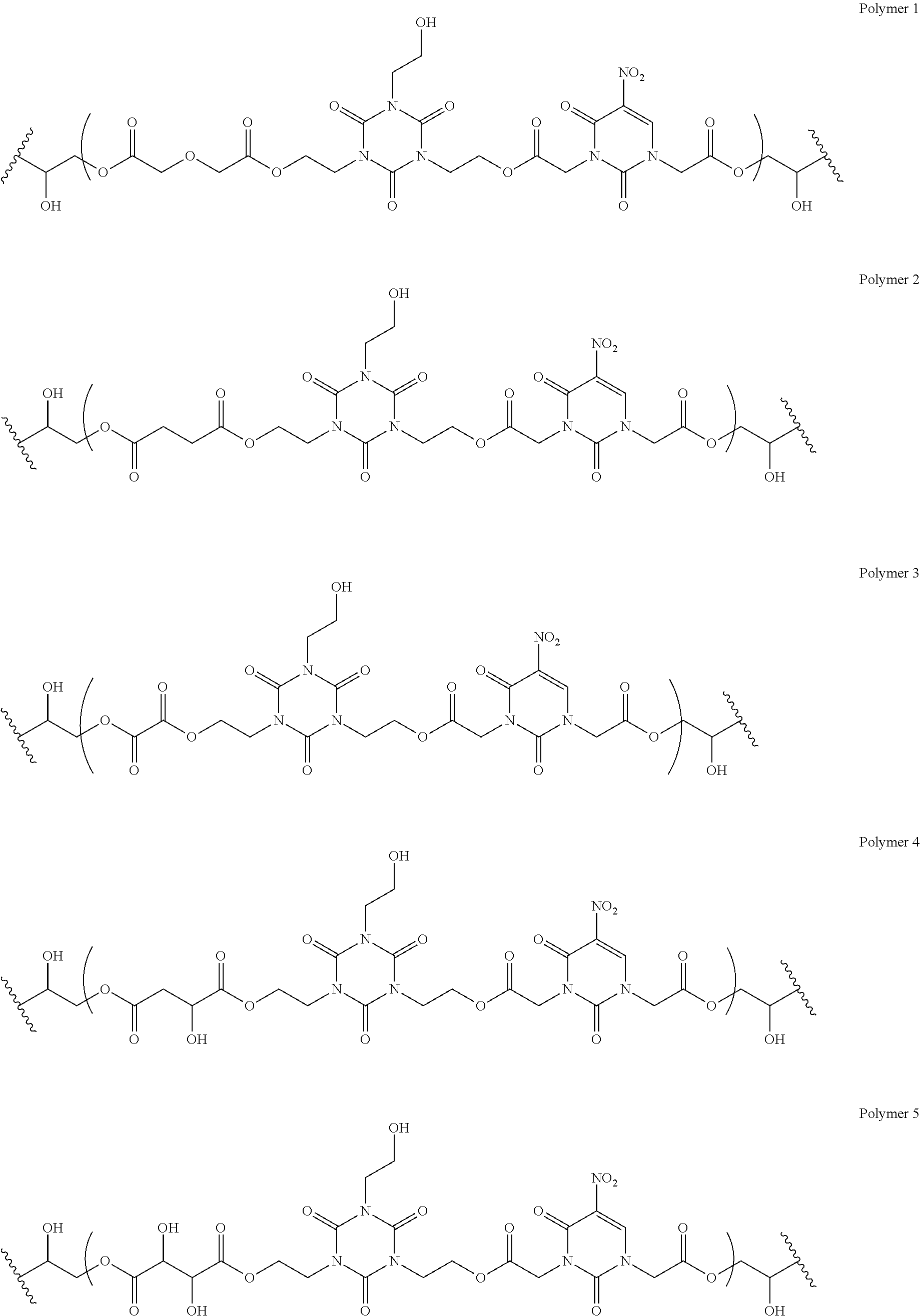

As referred to herein, suitable heteroalkyl include optionally substituted C₁₋₂₀ alkoxy, optionally substituted alkylthio preferably having 1 to about 20 carbon atoms; optionally substituted alkylsulfinyl preferably 1 to about 20 carbon atoms; optionally substituted alkylsulfonyl preferably having 1 to about 20 carbon atoms; and optionally substituted alkylamine preferably having 1 to about 20 carbon atoms.

It is also understood that the term “heteroalkyl” includes “heteroalicyclic” groups unless otherwise indicated. Heteroalicyclic groups are non-aromatic ring groups that have one or more hetero (e.g. N, O or S) ring atoms. Preferred heteroalicyclic groups have 5 to 20 ring atoms and 1, 2 or 3 N, O or S ring atoms.

The term “alkyl” refers to the radical of saturated aliphatic groups, including straight-chain alkyl groups, branched-chain alkyl groups, cycloalkyl (alicyclic) groups, alkyl substituted cycloalkyl groups, and cycloalkyl substituted alkyl groups. In preferred aspects, a straight chain or branched chain alkyl has 30 or fewer carbon atoms in its backbone (e.g., C₁-C₃₀ for non-cyclic, C₃-C₃₀ for branched chain), preferably 26 or fewer, and more preferably 20 or fewer, and still more preferably 4 or fewer.

It is also understood that the term “alkyl” includes “carbon alicyclic” groups unless otherwise indicated.

As referred to herein, the term “carbon alicyclic group” means each ring member of the non-aromatic group is carbon. The carbon alicyclic group can have one or more endocyclic carbon-carbon double bonds, provided the ring is not aromatic. The term optionally substituted “cycloalkyl group” means each ring member of the non-aromatic group is carbon and the carbon ring does not have any endocyclic carbon-carbon double bonds. For instance, cyclohexyl, cyclopentyl and adamantyl are cycloalkyl groups as well as carbon alicyclic groups. Carbon alicyclic groups and cycloalkyl groups may comprise one ring or multiple (e.g. 2, 3, 4 or more) bridged, fused or otherwise covalently linked rings.

As referred to herein, a “heteroaryl” group includes an aromatic 5-8 membered monocyclic, 8-12 membered bicyclic, or 11-14 membered tricyclic ring system having 1-3 heteroatoms if monocyclic, 1-6 heteroatoms if bicyclic, or 1-9 heteroatoms if tricyclic, said heteroatoms selected from O, N, or S (e.g., carbon atoms and 1-3, 1-6, or 1-9 heteroatoms of N, O, or S if monocyclic, bicyclic, or tricyclic, respectively), wherein 0, 1, 2, 3, or 4 atoms of each ring may be substituted by a substituent. Examples of heteroaryl groups include pyridyl, furyl or furanyl, imidazolyl, benzimidazolyl, pyrimidinyl, thiophenyl or thienyl, quinolinyl, indolyl, thiazolyl, and the like.

Various materials and substituents (including groups R, R′, R₁, R₂, A₁, A₂, A₃, and A₄ of Formulae (I), (II), (III) above) that are “optionally substituted” may be suitably substituted at one or more available positions by e.g. halogen (F, Cl, Br, I); nitro; hydroxy; amino; alkyl such as C₁₋₈ alkyl; alkenyl such as C₂₋₈ alkenyl; alkylamino such as C₁₋₈ alkylamino; carbocyclic aryl such as phenyl, naphthyl, anthracenyl; heteroaryl, and the like.

A variety of resins may serve as the resin components of an underlying coating composition.

Particularly preferred resins of coating compositions of the invention may comprise polyester linkages. Polyester resins can be readily prepared by reaction of one or more polyol reagents with one or more carboxy-containing (such as a carboxylic acid, ester, anhydride, etc.) compounds. Suitable polyol reagents include diols, glycerols and triols such as e.g. diols such as diol is ethylene glycol, 1,2-propylene glycol, 1,3-propylene glycol, butane diol, pentane diol, cyclobutyl diol, cyclopentyl diol, cyclohexyl diol, dimethylolcyclohexane, and triols such as glycerol, trimethylolethane, trimethylolpropane and the like.

Resins that comprise one or more substituted uracil moieties and one or more dicarboxylic acid groups may be readily prepared. For instance, monomers containing the desired groups may be polymerized. Preferred syntheses are set forth in the examples which follow.

Preferably resins of underlying coating compositions of the invention will have a weight average molecular weight (Mw) of about 1,000 to about 10,000,000 daltons, more typically about 2,000 to about 10,000 daltons, and a number average molecular weight (Mn) of about 500 to about 1,000,000 daltons. Molecular weights (either Mw or Mn) of the resins of compositions of the invention are suitably determined by gel permeation chromatography.

The resin component will be the major solids component of an underlying coating composition in many preferred embodiments. For instance, one or resins suitably may be present from 50 to 99.9 weight percent based on total solid content of a coating composition, more typically from 80 or 85 to 95, 98 or 99+(or even 100) weight percent based total solid content of a coating composition. As referred to herein, solids of a coating composition refer to all materials of the coating composition except solvent carrier.

As discussed above, in certain embodiments, a coating composition of the invention may comprise a crosslinker in addition to a resin or other material with substituted uracil moieties and aliphatic dicarboxylic acid groups. For example, coating compositions may include amine-based crosslinkers such as melamine materials, including melamine resins such as manufactured by Cytec Industries and sold under the tradename of Cymel 300, 301, 303, 350, 370, 380, 1116 and 1130; glycolurils including those glycolurils available from Cytec Industries; and benzoquanamines and urea-based materials including resins such as the benzoquanamine resins available from Cytec Industries under the name Cymel 1123 and 1125, and urea resins available from Cytec Industries under the names of Powderlink 1174 and 1196. In addition to being commercially available, such amine-based resins may be prepared e.g. by the reaction of acrylamide or methacrylamide copolymers with formaldehyde in an alcohol-containing solution, or alternatively by the copolymerization of N-alkoxymethyl acrylamide or methacrylamide with other suitable monomers.

Resins containing i) one or more substituted uracil moieties (e.g. formula (I)), ii) one or more reacted dicarboxylic acid groups (e.g. formula (III)), and/or iii) one or more isocyanurate moieties (e.g. formula (II)) of a coating composition of the invention in general is present in an amount of between about 5 and 100 weight percent of total solids (all components except solvent carrier) of the coating composition, more typically at least about 20, 30 40, 50, 60, 70, 80, 90 or 100 weight percent of total solids (all components except solvent carrier) of the coating composition.

Preferred coating compositions of the invention also may contain a thermal acid generator compound. Thermal-induced crosslinking of the coating composition by activation of the thermal acid generator is generally preferred.

Suitable thermal acid generator compounds for use in a coating composition include ionic or substantially neutral thermal acid generators, e.g. an ammonium arenesulfonate salt (e.g. toluene sulfonic acid ammonium salt), for catalyzing or promoting crosslinking during curing of an antireflective composition coating layer. Typically one or more thermal acid generators are present in an coating composition in a concentration from about 0.1 to 10 percent by weight of the total of the dry components of the composition (all components except solvent carrier), more preferably about 0.5 to 2 percent by weight of the total dry components.

Coating compositions of the invention, particularly for reflection control applications, also may contain additional dye compounds that absorb radiation used to expose an overcoated photoresist layer. Other optional additives include surface leveling agents, for example, the leveling agent available under the tradename Silwet 7604, or the surfactant FC 171 or FC 431 available from the 3M Company.

Underlying coating compositions of the invention also may contain other materials such as a photoacid generator, including a photoacid generator as discussed for use with an overcoated photoresist composition. See U.S. Pat. No. 6,261,743 for a discussion of such use of a photoacid generator in an antireflective composition.

To make a liquid coating composition of the invention, the components of the coating composition are dissolved in a suitable solvent such as, for example, one or more oxyisobutyric acid esters particularly methyl-2-hydroxyisobutyrate, ethyl lactate or one or more of the glycol ethers such as 2-methoxyethyl ether (diglyme), ethylene glycol monomethyl ether, and propylene glycol monomethyl ether; solvents that have both ether and hydroxy moieties such as methoxy butanol, ethoxy butanol, methoxy propanol, and ethoxy propanol; methyl 2-hydroxyisobutyrate; esters such as methyl cellosolve acetate, ethyl cellosolve acetate, propylene glycol monomethyl ether acetate, dipropylene glycol monomethyl ether acetate and other solvents such as dibasic esters, propylene carbonate and gamma-butyro lactone. The concentration of the dry components in the solvent will depend on several factors such as the method of application. In general, the solid content of an underlying coating composition varies from about 0.5 to 20 weight percent of the total weight of the coating composition, preferably the solid content varies from about 0.5 to 10 weight of the coating composition.

### Photoresists

Photoresists for use with an underlying coating composition typically comprise a polymer and one or more acid generators. Generally preferred are positive-tone resists and the resist polymer has functional groups that impart alkaline aqueous solubility to the resist composition. For example, preferred are polymers that comprise polar functional groups such as hydroxyl or carboxylate, or acid-labile groups that can liberate such polar moieties upon lithographic processing. Preferably the polymer is used in a resist composition in an amount sufficient to render the resist developable with an aqueous alkaline solution.

Acid generators are also suitably used with polymers that comprise repeat units containing aromatic groups, such as optionally substituted phenyl including phenol, optionally substituted naphthyl, and optionally substituted anthracene. Optionally substituted phenyl (including phenol) containing polymers are particularly suitable for many resist systems, including those imaged with EUV and e-beam radiation. For positive-acting resists, the polymer also preferably contains one or more repeat units that comprise acid-labile groups. For example, in the case of polymers containing optionally substituted phenyl or other aromatic groups, a polymer may comprise repeat units that contain one or more acid-labile moieties such as a polymer that is formed by polymerization of monomers of an acrylate or methacrylate compound with acid-labile ester (e.g. t-butyl acrylate or t-butyl methacrylate). Such monomers may be copolymerized with one or more other monomers that comprise aromatic group(s) such as optionally phenyl, e.g. a styrene or vinyl phenol monomer.

Preferred monomers used for the formation of such polymers include: an acid-labile monomer having the following formula (V), a lactone-containing monomer of the following formula (VI), a base-soluble monomer of the following formula (VII) for adjusting dissolution rate in alkaline developer, and an acid-generating monomer of the following formula (VIII), or a combination comprising at least one of the foregoing monomers:

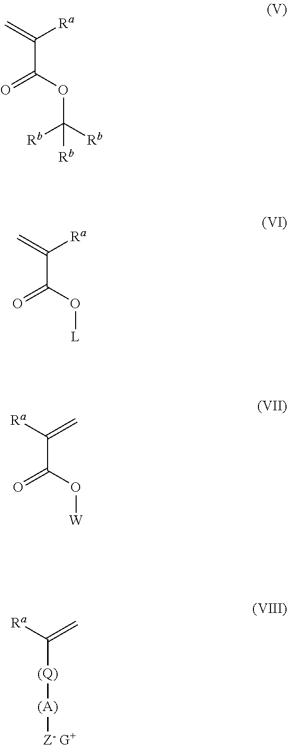

wherein each R^{a} is independently H, F, —CN, C₁₋₁₀ alkyl, or C₁₋₁₀ fluoroalkyl. In the acid-deprotectable monomer of formula (V), R^{b} is independently C₁₋₂₀ alkyl, C₃₋₂₀ cycloalkyl, C₆₋₂₀ aryl, or C₇₋₂₀ aralkyl, and each R^{b} is separate or at least one R^{b} is bonded to an adjacent R^{b} to form a cyclic structure. In lactone-containing monomer of formula (VI), L is a monocyclic, polycyclic, or fused polycyclic C₄₋₂₀ lactone-containing group. In the base solubilizing monomer of formula (VII), W is a halogenated or non-halogenated, aromatic or non-aromatic C₂₋₅₀ hydroxyl-containing organic group having a pKa of less than or equal to 12. In the acid generating monomer of formula (VIII), Q is ester-containing or non-ester containing and fluorinated or non-fluorinated and is C₁₋₂₀ alkyl, C₃₋₂₀ cycloalkyl, C₆₋₂₀ aryl, or C₇₋₂₀ aralkyl group, A is ester-containing or non-ester-containing and fluorinated or non-fluorinated, and is C₁₋₂₀ alkyl, C₃₋₂₀ cycloalkyl, C₆₋₂₀ aryl, or C₇₋₂₀ aralkyl, Z⁻ is an anionic moiety comprising carboxylate, sulfonate, an anion of a sulfonamide, or an anion of a sulfonimide, and G⁺ is a sulfonium or iodonium cation.
Exemplary acid-deprotectable monomers include but are not limited to:

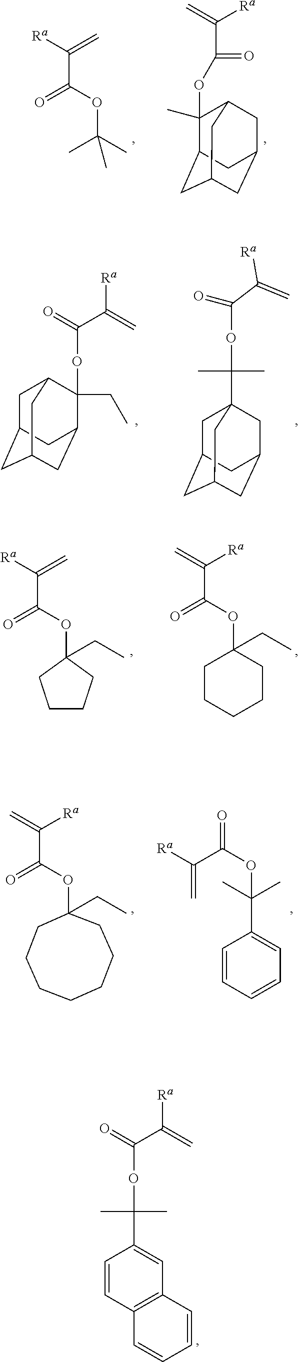

or a combination comprising at least one of the foregoing, wherein R^{a} is H, F, —CN, C₁₋₆ alkyl, or C₁₋₆ fluoroalkyl.
Suitable lactone monomers may be of the following formula (IX):

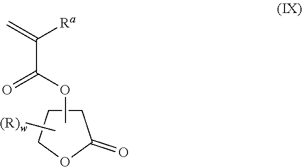

wherein R^{a} is H, F, —CN, C₁₋₆ alkyl, or C₁₋₆ fluoroalkyl, R is a C₁₋₁₀ alkyl, cycloalkyl, or heterocycloalkyl, and w is an integer of 0 to 5. In formula (IX), R is attached directly to the lactone ring or commonly attached to the lactone ring and/or one or more R groups, and the ester moiety is attached to the lactone ring directly, or indirectly through R.
Exemplary lactone-containing monomers include:

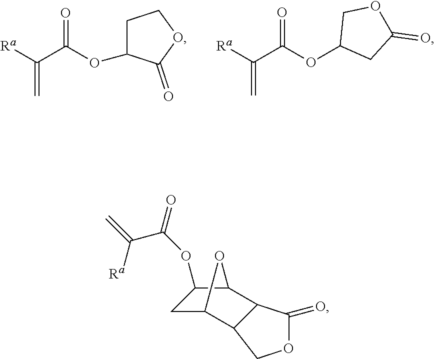

or a combination comprising at least one of the foregoing monomers, wherein R^{a} is H, F, —CN, C₁₋₁₀ alkyl, or C₁₋₁₀ fluoroalkyl.
Suitable base-soluble monomers may be of the following formula (X):

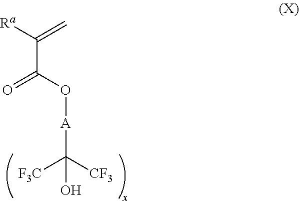

wherein each R^{a} is independently H, F, —CN, C₁₋₁₀ alkyl, or C₁₋₁₀ fluoroalkyl, A is a hydroxyl-containing or non-hydroxyl containing, ester-containing or non ester-containing, fluorinated or non-fluorinated C₁₋₂₀ alkylene, C₃₋₂₀ cycloalkylene, C₆₋₂₀ arylene, or C₇₋₂₀ aralkylene, and x is an integer of from 0 to 4, wherein when x is 0, A is a hydroxyl-containing C₆₋₂₀ arylene.
Exemplary base soluble monomers include those having the following structures:

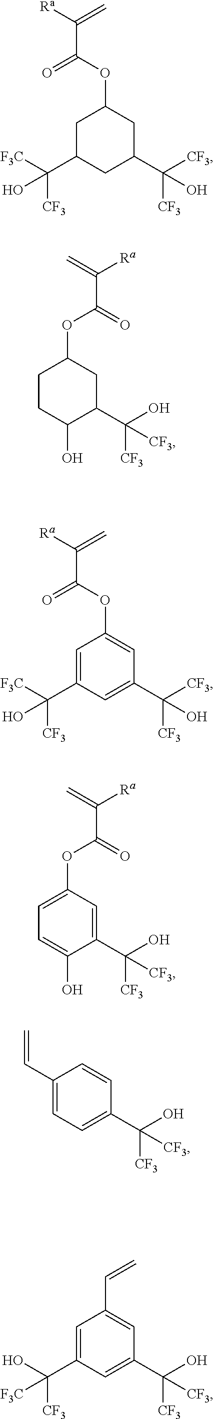

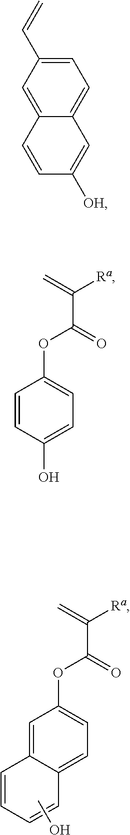

or a combination comprising at least one of the foregoing, wherein R^{a} is H, F, —CN, C₁₋₆ alkyl, or C₁₋₆ fluoroalkyl.

Preferred acid generating monomers include those of the formulae (XI) or (XII):

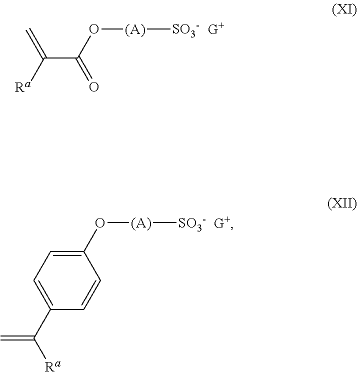

wherein each R^{a} is independently H, F, —CN, C₁₋₆ alkyl, or C₁₋₆ fluoroalkyl, A is a fluorine-substituted C₁₋₃₀ alkylene group, a fluorine-substituted C₃₋₃₀ cycloalkylene group, a fluorine-substituted C₆₋₃₀ arylene group, or a fluorine-substituted C₇₋₃₀ alkylene-arylene group, and G⁺ is a sulfonium or iodonium cation.

Preferably, in formulas (XI) and (XII), A is a —[(C(R¹)₂)ₓC(═O)O]_{b}—C((R²)₂)_{y}(CF₂)_{z}-group, or an o-, m- or p-substituted —C₆F₄— group, where each R¹ and R² are each independently H, F, —CN, C₁₋₆ fluoroalkyl, or C₁₋₆ alkyl, b is 0 or 1, x is an integer of 1 to 10, y and z are independently integers of from 0 to 10, and the sum of y+z is at least 1.

Exemplary preferred acid generating monomers include:

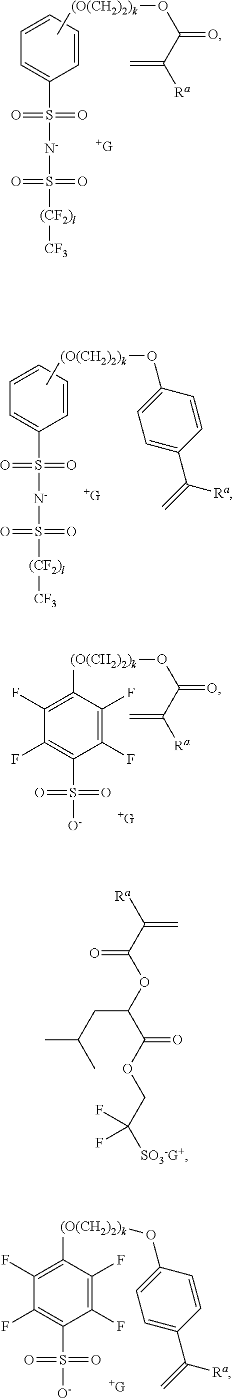

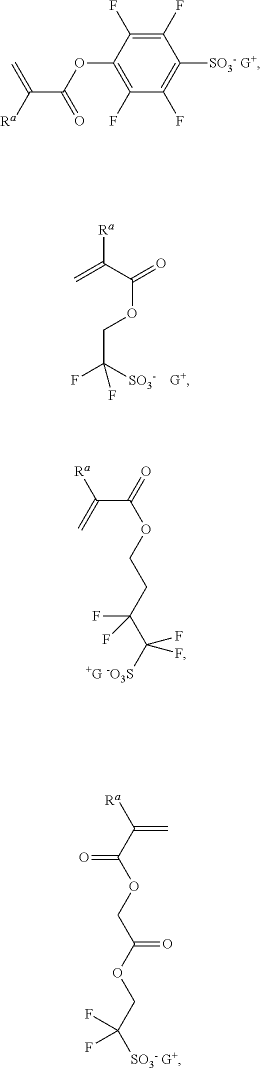

or a combination comprising at least one of the foregoing, where each R^{a} is independently H, F, —CN, C₁₋₆ alkyl, or C₁₋₆ fluoroalkyl, k is suitably an integer of from 0 to 5; and G⁺ is a sulfonium or iodonium cation. G⁺ as referred to herein throughout the various formulae may be an acid generator as disclosed herein and comprise an oxo-dioxolane moiety and/or an oxo-dioxane moiety.
Preferred acid-generating monomers may include sulfonium or iodonium cation. Preferably, in formula (IV), G⁺ is of the formula (XIII):

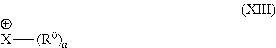

wherein X is S or I, each R⁰ is halogenated or non-halogenated and is independently C₁₋₃₀ alkyl group; a polycyclic or monocyclic C₃₋₃₀ cycloalkyl group; a polycyclic or monocyclic C₄₋₃₀ aryl group; or a combination comprising at least one of the foregoing, wherein when X is S, one of the R⁰ groups is optionally attached to one adjacent R⁰ group by a single bond, and a is 2 or 3, wherein when X is I, a is 2, or when X is S, a is 3.

Exemplary acid generating monomers include those having the formulas:

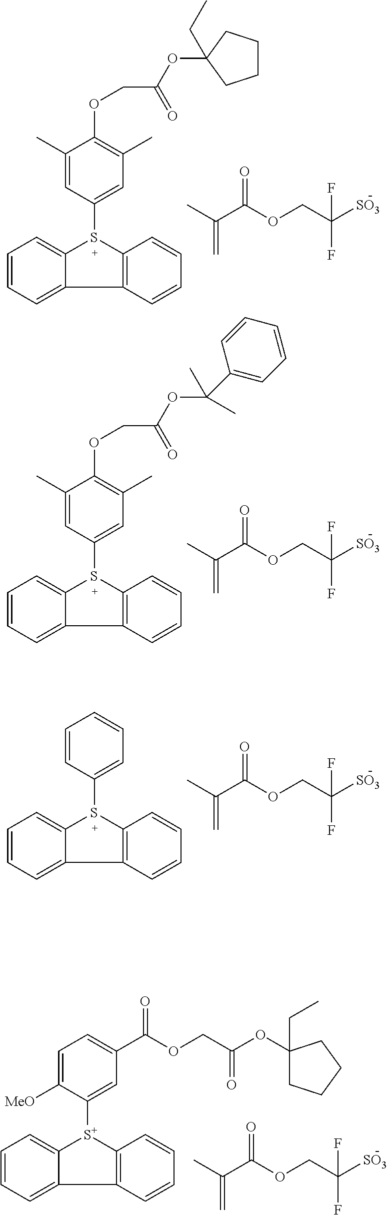

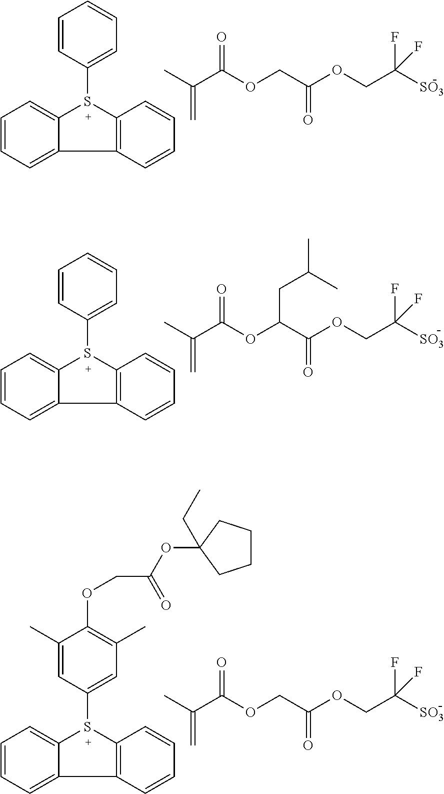

Specifically suitable polymers that have acid-labile deblocking groups for use in a positive-acting chemically-amplified photoresist of the invention have been disclosed in European Patent Application 0829766A2 (polymers with acetal and ketal polymers) and European Patent Application EP0783136A2 (terpolymers and other copolymers including units of 1) styrene; 2) hydroxystyrene; and 3) acid labile groups, particularly alkyl acrylate acid labile groups.

Additional preferred resins for use in photoresists to be imaged at sub-200 nm, such as at 193 nm, comprises units of the following general formulae (I), (II) and (III):

Preferred resins for use in photoresists to be imaged at sub-200 nm, such as at 193 nm, comprise units of the following general formulae (I), (II) and (III):

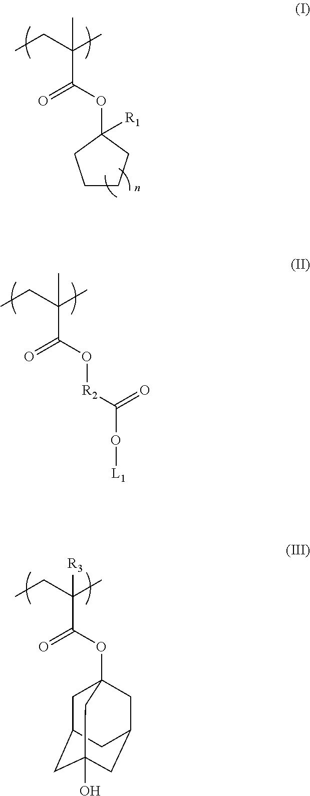

wherein: R₁ is a (C₁-C₃)alkyl group; R₂ is a (C₁-C₃)alkylene group; L₁ is a lactone group; and n is 1 or 2.

Polymers for use in photoresists of the invention may suitably vary widely in molecular weight and polydisperity. Suitable polymers include those that have an M_{w} of from about 1,000 to about 50,000, more typically about 2,000 to about 30,000 with a molecular weight distribution of about 3 or less, more typically a molecular weight distribution of about 2 or less.

Preferred negative-acting compositions of the invention comprise a mixture of materials that will cure, crosslink or harden upon exposure to acid, and two or more acid generators as disclosed herein. Preferred negative acting compositions comprise a polymer binder such as a phenolic or non-aromatic polymer, a crosslinker component and a photoactive component of the invention. Such compositions and the use thereof have been disclosed in European Patent Applications 0164248 and U.S. Pat. No. 5,128,232 to Thackeray et al. Preferred phenolic polymers for use as the polymer binder component include novolaks and poly(vinylphenol)s such as those discussed above. Preferred crosslinkers include amine-based materials, including melamine, glycolurils, benzoguanamine-based materials and urea-based materials. Melamine-formaldehyde polymers are often particularly suitable. Such crosslinkers are commercially available, e.g. the melamine polymers, glycoluril polymers, urea-based polymer and benzoguanamine polymers, such as those sold by Cytec under tradenames Cymel 301, 303, 1170, 1171, 1172, 1123 and 1125 and Beetle 60, 65 and 80.

Particularly preferred photoresists of the invention may be used in immersion lithography applications. See, for example, U.S. Pat. No. 7,968,268 to Rohm and Haas Electronic Materials for a discussion of preferred immersion lithography photoresists and methods.

Photoresists of the invention also may comprise a single acid generator or a mixture of distinct acid generators, typically a mixture of 2 or 3 different acid generators, more typically a mixture that consists of a total of 2 distinct acid generators. The photoresist composition comprises an acid generator employed in an amount sufficient to generate a latent image in a coating layer of the composition upon exposure to activating radiation. For example, the acid generator will suitably be present in an amount of from 1 to 20 wt % based on total solids of the photoresist composition.

Suitable acid generators are known in the art of chemically amplified photoresists and include, for example: onium salts, for example, triphenylsulfonium trifluoromethanesulfonate, (p-tert-butoxyphenyl)diphenylsulfonium trifluoromethanesulfonate, tris(p-tert-butoxyphenyl)sulfonium trifluoromethanesulfonate, triphenylsulfonium p-toluenesulfonate; nitrobenzyl derivatives, for example, 2-nitrobenzyl-p-toluenesulfonate, 2,6-dinitrobenzyl-p-toluenesulfonate, and 2,4-dinitrobenzyl-p-toluenesulfonate; sulfonic acid esters, for example, 1,2,3-tris(methanesulfonyloxy)benzene, 1,2,3-tris(trifluoromethanesulfonyloxy)benzene, and 1,2,3-tris(p-toluenesulfonyloxy)benzene; diazomethane derivatives, for example, bis(benzenesulfonyl)diazomethane, bis(p-toluenesulfonyl)diazomethane; glyoxime derivatives, for example, bis-O-(p-toluenesulfonyl)-α-dimethylglyoxime, and bis-O-(n-butanesulfonyl)-α-dimethylglyoxime; sulfonic acid ester derivatives of an N-hydroxyimide compound, for example, N-hydroxysuccinimide methanesulfonic acid ester, N-hydroxysuccinimide trifluoromethanesulfonic acid ester; and halogen-containing triazine compounds, for example, 2-(4-methoxyphenyl)-4,6-bis(trichloromethyl)-1,3,5-triazine, and 2-(4-methoxynaphthyl)-4,6-bis(trichloromethyl)-1,3,5-triazine.

As referred to herein, acid generators can produce an acid when exposed to activating radiation, such as EUV radiation, e-beam radiation, 193 nm wavelength radiation or other radiation sources. Acid generator compounds as referred to herein also may be referred to as photoacid generator compounds.

Photoresists of the invention also may contain other materials. For example, other optional additives include actinic and contrast dyes, anti-striation agents, plasticizers, speed enhancers and sensitizers. Such optional additives typically will be present in minor concentration in a photoresist composition. Alternatively, or in addition, other additives may include quenchers that are non-photo-destroyable bases, such as, for example, those based on hydroxides, carboxylates, amines, imines, and amides. Preferably, such quenchers include C₁₋₃₀ organic amines, imines, or amides, or may be a C₁₋₃₀ quaternary ammonium salt of a strong base (e.g., a hydroxide or alkoxide) or a weak base (e.g., a carboxylate). Exemplary quenchers include amines such as tripropylamine, dodecylamine, tris(2-hydroxypropyl)amine, oltetrakis(2-hydroxypropyl)ethylenediamine; aryl amines such as diphenylamine, triphenylamine, aminophenol, and 2-(4-aminophenyl)-2-(4-hydroxyphenyl)propane, a hindered amine such as diazabicycloundecene (DBU) or diazabicyclononene (DBN), or ionic quenchers including quaternary alkyl ammonium salts such as tetrabutylammonium hydroxide (TBAH) or tetrabutylammonium lactate.

Surfactants include fluorinated and non-fluorinated surfactants, and are preferably non-ionic. Exemplary fluorinated non-ionic surfactants include perfluoro C₄ surfactants such as FC-4430 and FC-4432 surfactants, available from 3M Corporation; and fluorodiols such as POLYFOX PF-636, PF-6320, PF-656, and PF-6520 fluorosurfactants from Omnova.
The photoresist further includes a solvent generally suitable for dissolving, dispensing, and coating the components used in a photoresists. Exemplary solvents include anisole, alcohols including ethyl lactate, 1-methoxy-2-propanol, and 1-ethoxy-2 propanol, esters including n-butylacetate, 1-methoxy-2-propyl acetate, methoxyethoxypropionate, ethoxyethoxypropionate, ketones including cyclohexanone and 2-heptanone, and a combination comprising at least one of the foregoing solvents.

### Lithographic Processing

In use, a coating composition of the invention is applied as a coating layer to a substrate by any of a variety of methods such as spin coating. The coating composition in general is applied on a substrate with a dried layer thickness of between about 0.02 and 0.5 μm, preferably a dried layer thickness of between about 0.04 and 0.20 μm. The substrate is suitably any substrate used in processes involving photoresists. For example, the substrate can be silicon, silicon dioxide or aluminum-aluminum oxide microelectronic wafers. Gallium arsenide, silicon carbide, ceramic, quartz or copper substrates may also be employed. Substrates for liquid crystal display or other flat panel display applications are also suitably employed, for example glass substrates, indium tin oxide coated substrates and the like. Substrates for optical and optical-electronic devices (e.g. waveguides) also can be employed.

Preferably the applied coating layer is cured before a photoresist composition is applied over the underlying coating composition. Cure conditions will vary with the components of the underlying coating composition. Particularly the cure temperature will depend on the specific acid or acid (thermal) generator that is employed in the coating composition. Typical cure conditions are from about 80° C. to 225° C. for about 0.5 to 5 minutes. Cure conditions preferably render the coating composition coating layer substantially insoluble to the photoresist solvent as well the developer solution to be used.

After such curing, a photoresist is applied above the surface of the applied coating composition. As with application of the bottom coating composition layer(s), the overcoated photoresist can be applied by any standard means such as by spinning, dipping, meniscus or roller coating. Following application, the photoresist coating layer is typically dried by heating to remove solvent preferably until the resist layer is tack free. Optimally, essentially no intermixing of the bottom composition layer and overcoated photoresist layer should occur.

The resist layer is then imaged with activating radiation such as 248 nm, 193 nm or EUV radiation through a mask in a conventional manner. The exposure energy is sufficient to effectively activate the photoactive component of the resist system to produce a patterned image in the resist coating layer. Typically, the exposure energy ranges from about 3 to 300 mJ/cm² and depending in part upon the exposure tool and the particular resist and resist processing that is employed. The exposed resist layer may be subjected to a post-exposure bake if desired to create or enhance solubility differences between exposed and unexposed regions of a coating layer. For example, negative acid-hardening photoresists typically require post-exposure heating to induce the acid-promoted crosslinking reaction, and many chemically amplified positive-acting resists require post-exposure heating to induce an acid-promoted deprotection reaction. Typically post-exposure bake conditions include temperatures of about 50° C. or greater, more specifically a temperature in the range of from about 50° C. to about 160° C.

The photoresist layer also may be exposed in an immersion lithography system, i.e. where the space between the exposure tool (particularly the projection lens) and the photoresist coated substrate is occupied by an immersion fluid, such as water or water mixed with one or more additives such as cesium sulfate which can provide a fluid of enhanced refractive index. Preferably the immersion fluid (e.g., water) has been treated to avoid bubbles, e.g. water can be degassed to avoid nanobubbles.

References herein to “immersion exposing” or other similar term indicates that exposure is conducted with such a fluid layer (e.g. water or water with additives) interposed between an exposure tool and the coated photoresist composition layer.

The exposed photoresist layer is then treated with a suitable developer capable of selectively removing portions of the film to form a photoresist pattern. In a negative tone development process, unexposed regions of a photoresist layer can be selectively removed by treatment with a suitable nonpolar solvent. See U.S. 2011/0294069 for suitable procedures for negative tone development. Typical nonpolar solvents for negative tone development are organic developers, such as a solvent chosen from ketones, esters, hydrocarbons, and mixtures thereof, e.g. acetone, 2-hexanone, 2-heptanone, methyl acetate, butyl acetate, and tetrahydrofuran. Photoresist materials used in the NTD process preferably form a photoresist layer that can form a negative image with organic solvent developer or a positive image with aqueous base developer such as tetraalkylammonium hydroxide solution. Preferably, the NTD photoresist is based on a polymer having acid sensitive (deprotectable) groups which, when deprotected, form carboxylic acid groups and/or hydroxyl groups.

Alternatively, development of the exposed photoresist layer can be accomplished by treating the exposed layer to a suitable developer capable of selectively removing the exposed portions of the film (where the photoresist is positive tone) or removing the unexposed portions of the film (where the photoresist is crosslinkable in the exposed regions, i.e., negative tone). Preferably, the photoresist is positive tone based on a polymer having acid sensitive (deprotectable) groups which form carboxylic acid groups when deprotected, and the developer is preferably a metal-ion free tetraalkylammonium hydroxide solution, such as, for example, aqueous 0.26 N tetramethylammonium hydroxide. A pattern forms by developing.

The developed substrate may then be selectively processed on those substrate areas bared of photoresist, for example, chemically etching or plating substrate areas bared of photoresist in accordance with procedures well known in the art. Suitable etchants include a hydrofluoric acid etching solution and a plasma gas etch such as an oxygen plasma etch. A plasma gas etch removes the underlying coating layer.

As discussed, in certain aspects, a wet etch process may be suitably employed. Wet etching may be suitably carried out by exposing the surface to be etched (e.g. a metal nitride, or metal nitride coated with one or more organic and/or inorganic layers) with a wet etch composition for a time and temperature effective to etch the surface (e.g. metal nitride surface and/or coating layers thereon). Exemplary wet etching compositions include an aqueous mixture of ammonium hydroxide and a peroxide such as hydrogen peroxide, or a mixture of an acid such as sulfuric acid and a peroxide such as hydrogen peroxide. See US 2006/0226122 for exemplary compositions. The examples which follow also provide exemplary wet etch process conditions. As referred to herein, a “wet etch process” means treating substrate areas defined by a adjoining photoresist (after development of the photoresist image) with a fluid composition typically either acid or alkaline in combination with a peroxide agent, but in any event distinguished from a plasma dry etch.

The following non-limiting examples are illustrative of the invention.

### Polymer Synthesis

### Comparative Polymer Example 1

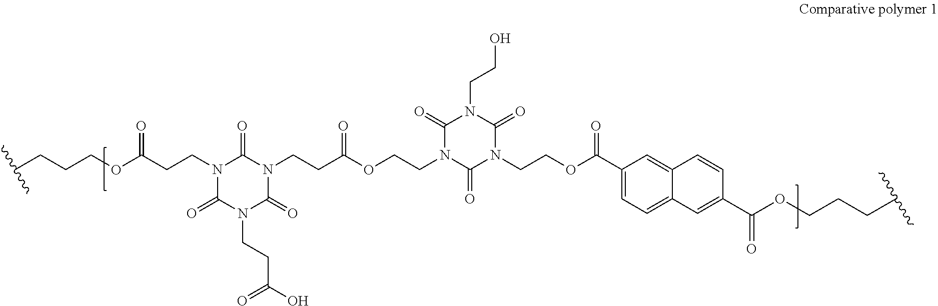

A 3-necked 250 ml round bottom flask was charged with 28.6 g of tris(2-hydroxyethyl)isocyanurate, 7.2 g of tris(2-carboxyethyl)isocyanurate, 14.3 g of dibutylnaphthalene dicarboxylate, 50.0 g of 1,4-budanediol, 0.33 g of para-toluene sulfonic acid mono-hydrate as a catalyst, 33.3 g of anisole as a solvent. It was heated up to a set temperature (155° C.) with stirring. The reaction mixture was run for 7 hs and then cooled the solution to the room temperature. Crude was diluted with THF (50 g) for the isolation. Reaction mixture was precipitated with mixture of methyl tert-butyl ether and isopropyl alcohol (×10 excess of reaction mixture) and then filtrated and vacuum dried for 24 hrs at 40° C. Fully dried powder was diluted to 15 wt %. Second isolation step is same with the first step.

### Comparative Polymer Example 2

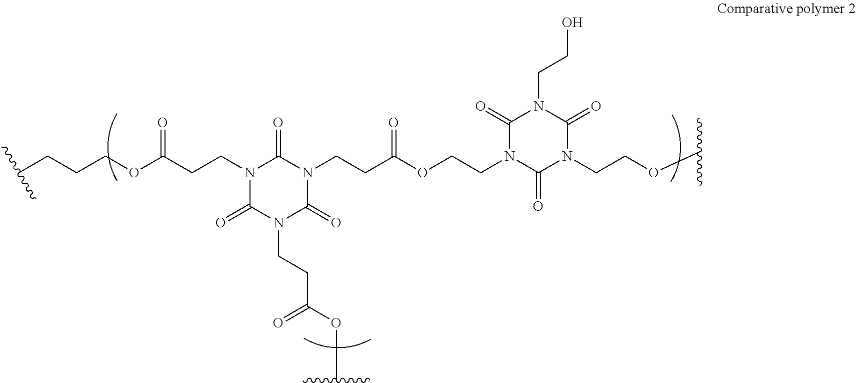

A 3-necked 250 ml round bottom flask was charged with 30.4 g of tris(2-hydroxyethyl)isocyanurate, 20.1 g of tris(2-carboxyethyl)isocyanurate, 20.1 g of 1,4-budanediol, 0.54 g of para-toluene sulfonic acid mono-hydrate as a catalyst, 34.2 g of anisole as a solvent. It was heated up to a set temperature (150° C.) with stirring. The reaction mixture was run for 3.5 hs and then cooled the solution to the room temperature. Crude was diluted with THF (80 g) for the isolation. Reaction mixture was precipitated with isopropyl alcohol (×10 excess of reaction mixture) and then filtrated and vacuum dried for 24 hrs at 40° C. Fully dried powder was diluted to 15 wt %. Second isolation step is same with the first step.

### Polymer Example 1

A 3-necked 250 ml round bottom flask was charged with 14.6 g of tris(2-hydroxyethyl)isocyanurate, 5.4 g of 5-nitro uracil, 9.4 g of di-glycolic acid, 10.6 g of 1,2-propandiol, 0.53 g of para-toluene sulfonic acid mono-hydrate as a catalyst, 40 g of anisole as a solvent. It was heated up to a set temperature (150° C.) with stirring. The reaction mixture was run for 9 hs and then cooled the solution to the room temperature. Crude was diluted with THF (80 g) for the isolation. Reaction mixture was precipitated with isopropyl alcohol (×10 excess of reaction mixture) and then filtrated and vacuum dried for 24 hrs at 40° C. Fully dried powder was diluted to 15 wt %. Second isolation step is same with the first step.

### BARC Composition

### Comparative BARC Example 1

3.198 g of the comparative polymer 1, 0.570 g of a tetra methoxy methyl glycoluril as a crosslinker, 0.030 g of ammonium p-toluenesulfonate salt, and 0.002 g of polyfox 656 as a leveling agent were dissolved in 96.2 g of mixture solvents (HBM/GBL 90/10 wt/wt) to obtain the solution. All the prepared solutions were filtered through an ultrahigh molecular weight polyethylene membrane filter. The solution was coated on a silicon wafer using a spinner and the wafer was heated at 205 C for 1 minute on a hot plate to form an anti-reflective coating. Measurement of the anti-reflective coating by a spectral ellipsometer indicated a refractive index n of 1.89 and optical extinction coefficient k of 0.29 at 193 nm.

### Comparative BARC Example 2

5.583 g of the comparative polymer 2, 0.297 g of a tetra methoxy methyl glycoluril as a crosslinker, 0.047 g of tri-ethylammonium p-toluenesulfonate salt, and 0.003 g of polyfox 656 as a leveling agent were dissolved in 94.07 g of HBM solvent to obtain the solution. All the prepared solutions were filtered through an ultrahigh molecular weight polyethylene membrane filter. The solution was coated on a silicon wafer using a spinner and the wafer was heated at 205 C for 1 minute on a hot plate to form an anti-reflective coating. Measurement of the anti-reflective coating by a spectral ellipsometer indicated a refractive index n of 1.96 and optical extinction coefficient k of 0.29 at 193 nm.

### BARC Example 3

3.407 g of the polymer 1, 0.611 g of a tetra methoxy methyl glycoluril as a crosslinker, 0.05 g of 2,4,6-Trimethylpyridinium p-toluenesulfonate salt, and 0.002 g of polyfox 656 as a leveling agent were dissolved in 95.93 g of HBM solvent to obtain the solution. All the prepared solutions were filtered through an ultrahigh molecular weight polyethylene membrane filter. The solution was coated on a silicon wafer using a spinner and the wafer was heated at 205 C for 1 minute on a hot plate to form an anti-reflective coating. Measurement of the anti-reflective coating by a spectral ellipsometer indicated a refractive index n of 1.83 and optical extinction coefficient k of 0.20 at 193 nm.

### Etch Rate Evaluation

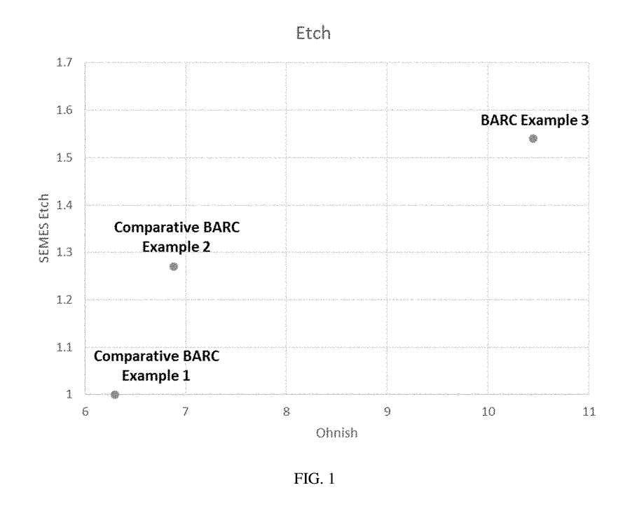

Etch rates with H2/N2 were determined with CCP type etcher using the following conditions: gas flow 400 H2/700 N2 for 12 sec, 20 mT RF Power, temperature: 20° C. Two wafers were coated with BARC, spun at 1500 rpm, and baked at 205° C. The film thickness was measured. The BARC-coated wafers were then etched for 12 s. The film thickness of each BARC was measured again. Ohnishi parameter values of the polymers of the compositions were also calculated. The results are shown in FIG. 1 and the following Table 1.

TABLE 1

| | | Etch Rate |
|---|---|---|
| Sample | Ohnishi Parameter | (vs reference 1) |
| Comparative | 6.30 | 1.00 |
| BARC Example 1 | | |
| Comparative | 6.88 | 1.27 |
| BARC Example 2 | | |
| BARC Example 3 | 10.45 | 1.54 |

1. A coated substrate comprising:
(a) a layer of a coating composition on a substrate, the coating composition comprising a resin that comprises one or more substituted uracil moieties and one or more reacted dicarboxylic acid groups; and
(b) a photoresist layer over the coating composition layer.

2. The substrate of claim 1 wherein the resin further comprises one or more isocyanurate moieties.

3. The substrate of claim 1, wherein uracil moieties are substituted with halo or nitro groups.

4. The substrate of claim 1, wherein the resin is obtainable by polymerizing 1) a first reagent that comprises one or more substituted uracil moieties and 2) a second reagent that comprises one or more aliphatic dicarboxylic acid groups.

5. The substrate of claim 1 wherein the resin is obtainable by polymerizing 1) a first reagent that comprises one or more substituted uracil moieties, 2) a second reagent that comprises one or more dicarboxylic acid groups and 3) a third reagent that comprises one or more isocyanurate moieties.

6. The substrate of claim 1 wherein the resin comprises the uracil and reacted dicarboxylic acid components in an amount of 20 to 70 weight percent based on resin total weight.

7. The substrate of claim 1 wherein the resin comprises polyester linkages.

8. A method of forming a photoresist relief image, comprising:
(a) applying a coating composition on a substrate, the coating composition comprising a resin that comprises one or more substituted uracil moieties and one or more reacted dicarboxylic acid groups;
(b) applying a photoresist composition above the coating composition layer; and
(c) exposing and developing the photoresist layer to provide a resist relief image.

9. An antireflective composition for use with an overcoated photoresist composition, the antireflective composition comprising a resin that comprises one or more substituted uracil moieties and one or more reacted dicarboxylic acid groups.

10. The antireflective composition of claim 9, wherein the resin further comprises one or more isocyanurate moieties.

11. The antireflective composition of claim 9 wherein the resin comprises polyester linkages.

12. The antireflective composition of claim 9 wherein the composition comprises a crosslinker component.

13. The coated substrate of claim 1 wherein the one or more diacid groups do not have aromatic substitution.

14. The coated substrate of claim 1 wherein the resin has an Ohnishi parameter value of at least 7.

15. The coated substrate of claim 1 wherein the resin has an Ohnishi parameter value of 8 to 12.

16. The coated substrate of claim 1 wherein one or more dicarboxylic acid groups correspond to a formula (III) 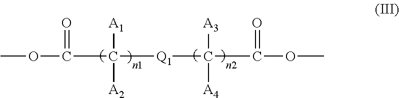
wherein in Formula (III):
n1 and n2 may independently be an integer from 0 to 100;
Q₁ may be independent a bond, —O—, —S—, —NHR— or —CRR′—;
A₁, A₂, A₃ and A₄ may be independently hydrogen, aliphatic groups (e.g. C₁-C₁₂ alkyl), or substituted or unsubstituted C₁-C₁₂ heteroalkyl (e.g. C₁-C₁₂ alkyl alcohol); and
R and R′ are independently hydrogen, C₁-C₄ alkyl, or C₁-C₄ alkyl alcohol.

17. The coated substrate of claim 16 wherein n1 and n2 are independently 0 to 5.

18. The coated substrate of claim 1 wherein the one or more dicarboxylic acid groups are selected from:

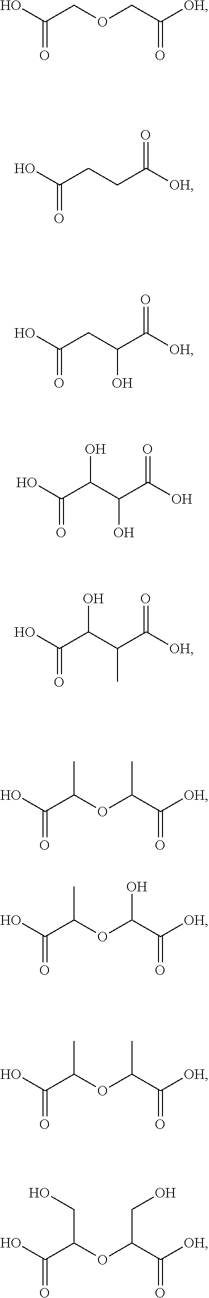

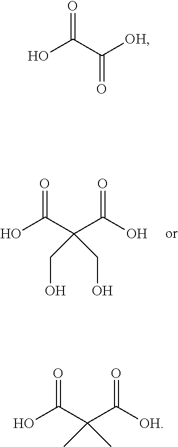

19. The antireflective composition of claim 9 wherein one or more dicarboxylic acid groups correspond to a formula (III) 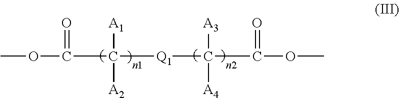
wherein in Formula (III):
n1 and n2 may independently be an integer from 0 to 100;
Q₁ may be independent a bond, —O—, —S—, —NHR— or —CRR′—;
A₁, A₂, A₃ and A₄ may be independently hydrogen, aliphatic groups (e.g. C₁-C₁₂ alkyl), or substituted or unsubstituted C₁-C₁₂ heteroalkyl (e.g. C₁-C₁₂ alkyl alcohol); and
R and R′ are independently hydrogen, C₁-C₄ alkyl, or C₁-C₄ alkyl alcohol.

20. The antireflective composition of claim 9 wherein the one or more dicarboxylic acid groups are selected from: 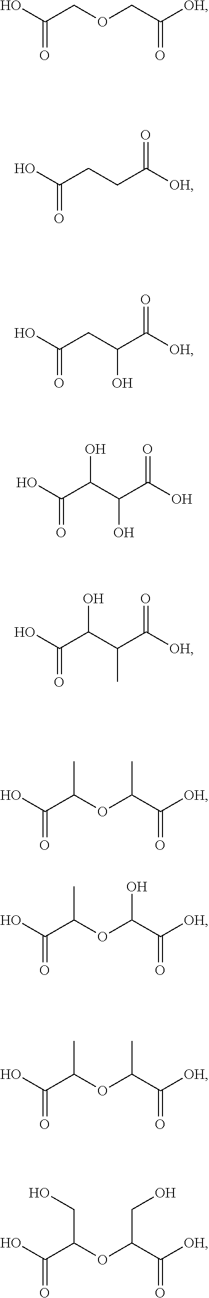 [chemical structure]
